(19) United States
(12) Patent Application Publication
(10) Pub. No.: US 2025/0257657 A1
(43) Pub. Date: Aug. 14, 2025

(54) APPARATUS AND METHOD DESIGNING CHARGING AND BLASTING FOR STOPE EXCAVATION

(71) Applicant: SANDVIK MINING AND CONSTRUCTION OY, Tampere (FI)

(72) Inventors: Jouko MUONA, Tampere (FI); Petteri HYVONEN, Tampere (FI); Tuomas KOKKONIEMI, Tampere (FI)

(21) Appl. No.: 19/047,801

(22) Filed: Feb. 7, 2025

(30) Foreign Application Priority Data
Feb. 8, 2024 (EP) 24156592.8

(51) Int. Cl. E21C 37/00; E21C 41/22; G06F 30/20

(52) U.S. Cl. CPC E21C 37/00; E21C 41/22; G06F 30/20; E21C 2100/00

(57) ABSTRACT

An apparatus and method for assisting design of charging and blasting of stopes in an underground stope excavation is provided. The apparatus includes a data processing device and is provided with data on realized drill holes drilled for the stope. The apparatus is also provided with data on an initial free space located below the stope. The apparatus assists in dividing an initial first stope ring into several blast sections, which are blasted in several partial blasts towards an available free space. The apparatus estimates volumes of rock materials, compares the estimated volumes to available free volumes and then examines whether the selected blast section fits in blasted expanded state into the available free space.

### RELATED APPLICATION DATA

This application claims priority under 35 U.S.C. § 119 to European Patent Application No. 24156592.8, filed on Feb. 8, 2024, which the entirety thereof is incorporated herein by reference.

### TECHNICAL FIELD

The invention relates to a stope excavation in an underground mine. More specifically the invention relates to an apparatus including at least one data processing device for assisting designing charging and blasting of drill holes of several vertical stope rings for the stope excavation. The invention further relates to a method for assisting designing charging and blasting of drill holes of vertical stope rings for a stope excavation.

### BACKGROUND

Stope excavation is an underground mining technique wherein desired ore is extracted from an underground mine. In general, the stope excavation typically comprises several successive vertical or slightly inclined stope rings of rock material, which are each blasted separately in partial blasts towards a premade free space below the stopes. After the first stope ring is entirely blasted and emptied, there is a free space for the following stope ring blasts not only below but also in lateral direction. Thus, the blasting of the first stope ring is a critical phase since there is only a limited free space below the first stope ring.

Designing charging and blasting plans for the stope excavation is a demanding and time consuming task. Further, it has been noted that there may exist unwanted variations in blasting results because of defects in the charging and blasting plans.

### SUMMARY

An object of the invention is to provide a novel and improved apparatus and method for assisting designing charging and blasting of drill holes of vertical stope rings.

An idea of the disclosed solution is that a designer is provided with an apparatus for assisting designing charging and blasting of drill holes of several vertical stope rings utilized in a stope excavation in an underground mine. Each stope ring includes two or more parallel or near parallel drill hole fans provided with several downwards or upwards directed drill holes.

The apparatus includes one or more data processing devices and is provided with data on realized drill holes drilled for a stope and is also provided with data on an initial free space located below or at least partly below the stope.

The apparatus assists in dividing an initial first stope ring into several blast sections, which are configured to be blasted in several partial blasts towards an available free space including at least the initial free space.

The apparatus estimates volume of rock material of selected blast sections in solid non-blasted state and also in blasted expanded state. The apparatus further estimates the volume of the available free space at the first stope ring. Furthermore, the apparatus compares the volume of the selected blast section in the blasted expanded state to the volume of the available free space and indicates, based on the comparison, when the selected blast section fits in the blasted expanded state into the available free space.

In other words, the apparatus can provide valuable information for designing the charging and blasting order of different blast sections of the first stope ring. When this data is implemented, it is possible to avoid problems in the blasting process.

A proper blasting requires that there is sufficient volume for the rock material being blasted and expanded. Thereby, an advantage of the disclosed solution is that a possible stope blocking problem can be effectively avoided. Then complicated and dangerous corrective drilling and blasting measures are not needed and the stope blasting process can proceed smoothly and effectively.

In the stope excavation the drill holes are long holes, which serve as blast holes and which extend from an upper premade horizontal space, such as an upper drift, towards a lower premade horizontal space, such as a lower drift. Thus, the upper drift serves as a first passage for executing the drilling and charging, whereas the lower drift serves as a second passage for emptying the free space by means of a wheel loader type mining vehicle, for example. Most of the drill holes are arranged in a fan like pattern whereby only some of them are open to the lower drift.

However, it is also possible to drill the drill holes from the lower drift towards the surface, i.e., the drilling is done from the bottom up. Charging of the drill holes can be done from the upper drift. Also in this alternative case, the blasted rock is designed to fall to the lower drift wherefrom the broken rock material is emptied.

The disclosed stope excavation is an effective mining technique wherein rock material is excavated in partial blast and wherein gravity and throw of the blast is utilized for moving the blasted broken rock material towards the lower drift below the blasted stope.

According to an embodiment, the data processing device of the apparatus is provided with at least one computer program product and execution of the computer program product is configured to execute the disclosed steps for assisting the charging and blasting design work of a designer.

According to an embodiment, each stope ring includes two or more parallel or substantially parallel drill hole fans provided with several drill holes.

According to an embodiment, the apparatus is provided with data on the magnitude of expansion of the rock material of the stope. The apparatus may be provided with data on rock type and quality of an ore body and the apparatus may consider the rock data when estimating the expansion of the blasted rock material.

Alternatively, the apparatus may be provided with a swell factor of the blasted rock, whereby the apparatus may calculate the volume of the blasted rock material when the volume in the solid state is known. Typically, the blasted rock material contains 25-30 percent voids and therefore needs more space compared to solid non-blasted rock.

The available free space expands gradually when the blast sections are blasted, and when the blast broken rock material is emptied through the initial free space below the stope. The initial free space may thereby serve as a space to receive the blasted rock material and also as a hauling passage below the stope. The blasting process includes emptying the free space between the blasting sequences. Each following blast section can have larger volume than the previous blast section since an enlarged available total free space is provided after each partial blast.

Thus, the available free space is a currently available free space which expands when the successive partial blasts of the selected blast sections proceed further.

The vertically downwards directed drill holes of the vertical stope form a fan-shaped pattern and are drilled using the implementing downwards directed fan drilling method. The drill holes are drilled to a floor of the upper drift by means of a long-hole rock drilling rig. Then drill hole openings are located on the floor of the upper drift. The drill holes are blast holes, which are charged with blasting material inserted to the drill holes from the upper drift by means of a charging rig.

Alternatively, the vertically upwards directed drill holes of the vertical stope are drilled to a roof of the lower drift by means of a long-hole rock drilling rig. The drill holes are charged with blasting material from the lower drift. In this alternative an upper drift is not necessarily needed since the operation utilizes the lower drift.

According to an embodiment, the apparatus is configured to assist designing a slot for the first stope ring. And further, the apparatus is configured to assist in dividing the slot into at least two partial slots one on top of the other. A first partial slot is located closest to the initial free space and is provided with a prior blasting order than a second partial slot vertically above the first partial slot. The apparatus is configured to estimate volume of rock material in the blasted expanded state of the first partial slot and compares the estimated volume to the volume of the initial free space.

In other words, the apparatus calculates the blasted volume of the first blast section of the initial first stope ring, i.e., the first partial slot, wherefrom the entire blasting process of the stope starts.

In the stope excavation the length of the slot is great whereby the whole length of the slot cannot be blasted in one go, as the expanding rock volume does not fit into the free volume of the existing drift below the stope.

The present apparatus can help the designer to set the lengths of the partial slots so that magnitudes of the volumes are suitable. Thus, charging of the slot is executed in accordance with the designed partial slots. And of course, blasting order of the partial slots is also determined.

An advantage of the solution is that assistance is provided for a designer to divide the slot into two or more blast sections, i.e., into the partial slots, so that the blasted rock material of the first blast fits reliably into the initial free space. This way problems in blasting of the slot may be avoided and smooth start for the blasting of the first stope ring is ensured. Blasting efficiency and safety may be improved when stope slot blocking can be diminished.

Blasting of the slot is typically the most critical phase in the stope blasting process. Assistance for this critical phase is provided by means of the present apparatus.

After the blast of the first partial slot, the initial free space is emptied, and the second partial slot is blasted thereafter. When the entire slot is blasted, then other blast sections widening the slot can be blasted.

The slot includes several vertical, or substantially vertical, free slot holes at a vertical center part of the slot and several substantially vertical blast holes surrounding the free slot holes. The free slot holes are not charged with explosives. The free slot holes extend to the lower drift and may have greater diameters than the surrounding blast holes.

One purpose of the free slot holes is to provide some central space inside the slot and to thereby assist the blasting and fragmentation of the rock material. In other words, the free slot holes create initial free volume for expanding rock mass during the blast.

According to an embodiment, the apparatus provides, on a display device, at least two selectable views of the first stope ring in different view angles. The apparatus is also configured to define and present the blast sections of the first stope ring in response to instructions input to the apparatus.

In other words, the apparatus provides a visual tool for a designer to define the blast sections on the display device. This way the design work of the blast sections of the first stope ring is intuitive. Further, the apparatus can provide immediate response and notice for the designer if the volume of the planned blast section does not fit into the available free space. Then possible amendments are easy and quick to execute.

According to an embodiment, the apparatus is configured to automatically generate a proposal of the blast sections of the first stope ring. Then the apparatus considers automatically also the volumes of the blasted rock material in relation to the available free space.

In order to implement the automatic feature, the apparatus may be provided with an excavation plan including data on shape of the stope and data on an initial free space below the stope. Further, the apparatus may be provided with realized drilling data on drill holes drilled for the stope.

According to an embodiment, the apparatus is configured to present in at least one of the views the drill holes in relation to the following limiting elements: outlines of a horizontal lower drift serving as the initial free space; outlines of a horizontal upper drift serving as a passage for the charging and comprising openings of the drill holes; and boundary lines of an ore body at the first stope ring.

According to an embodiment, the apparatus is configured to provide on a display device a top view and a side view of drill holes of the first stope ring. The top view is a presentation of start points and projections of angles of the drill holes. The side view is a presentation of the drill holes in a fan pattern and in relation to the outlines of the horizontal drifts and the boundaries of the ore body.

According to an embodiment, the apparatus is provided with realized data on drill holes drilled for the first stope ring. The realized data includes properties of the drilled rock material surrounding the drill holes of the first stope whereby the apparatus is configured to take the rock data into account when estimating the amount of the expansion of the rock material of each blast section of the first stope ring.

The gathered data on properties of the drilled rock material can also be used for providing suggestion on the amount of a charge used for each drill hole of each blast section.

According to an embodiment, the apparatus is configured to provide a designer advice for setting boarders of the selected blast section so that that the volume of the selected blast section in the blasted state matches with the available free space on the basis of the executed comparison.

According to an embodiment, the apparatus is configured to generate suggestions on the divide of the blast sections. Then the apparatus calculates suitable sizes for each blast section and provides a proposal of boarders limiting the blast sections. In this embodiment, a higher level of automation is implemented. However, the designer makes the final decisions on the created charging plan.

According to an embodiment, the apparatus is configured to provide a warning, a notice, or a visual indication on the display device for the designer if the volume of the selected blast section is too big and needs to be limited. This is a relatively simple way to assist the designer to create proper charging plans.

According to an embodiment, the apparatus is configured to determine the charging depth for drill holes of the first stope ring based on realized drill data of the drill holes and set boarders of the blast sections.

In other words, the apparatus can assist the designer by providing data on charging depths, i.e., insertion depths of the charges, for blast holes at each blast section. The designer can then decide the amount of blast material and implemented detonators. The charging work is facilitated, and the blasting can be more accurate when the charges are correctly positioned.

According to an embodiment, the apparatus may generate a charging plan for the first stope ring. The charging plan can be submitted to a charging device or a special charging rig for executing mechanized charging. The charging plan may include data on the charging depth, amount and type of blast material, used detonators, and blasting order.

According to an embodiment, the charging plan generated by the apparatus may include at least two separate charges at different charging depths for at least some of the drill holes, which are crossing at least two different blast sections. In other words, the downwards directed drill fan includes drill holes that are directed so that they cross two or more blast sections and then the drill holes participate in the partial blast of two or more blast sections. The apparatus defines insertion depths, i.e., positions inside the drill holes, for the two or more charges of the drill holes. The defined insertion depths can be submitted to the charging rig for providing automated charging.

According to an embodiment, the charging rig is configured to adjust the amount of inserted blasting material in function of length of the drill hole. Thus, the charging rig includes an adjustable blasting material feature.

According to an embodiment the disclosed solution relates also to a method for assisting designing charging and blasting of drill holes of several vertical stope rings in a stope excavation in an underground mine The method includes using at least one data processing device in the designing process; receiving data on realized drill holes drilled for a stope; receiving data on an initial free space located at least partly below the stope; assisting in dividing an initial first stope ring into several blast sections which are configured to be blasted in several partial blasts towards an available free space including at least the initial free space; estimating volume of rock material of selected blast sections in solid non-blasted state and in blasted expanded state; estimating volume of the available free space at the first stope ring; comparing the volume of the selected blast section in the blasted expanded state to the volume of the available free space; and indicating, based on the comparison, when the selected blast section fits in the blasted expanded state into the available free space.

The foregoing summary, as well as the following detailed description of the embodiments, will be better understood when read in conjunction with the appended drawings. It should be understood that the embodiments depicted are not limited to the precise arrangements and instrumentalities shown.

### BRIEF DESCRIPTION OF THE DRAWINGS

Some embodiments are described in more detail in the accompanying drawings, in which

FIG. 1 is a schematic side view showing a rock drilling rig executing long hole drilling in a drift.

FIG. 2 is a schematic view showing a drill hole fan drilled from an upper drift towards a lower drift.

FIG. 3 is a schematic view showing a drill hole fan drilled from a lower drift towards an upper drift.

FIG. 4a is a schematic view showing a drilled fan of several drill holes and FIG. 4b shows progress of a stope excavation process in several successive stope rings.

FIGS. 5a-5c are schematic side views showing blasting of an initial first stope ring and progress of blasting process thereafter.

FIG. 6 is a schematic view showing charging from an upper drift and emptying of a heap of blasted rock material via a lower drift.

FIGS. 7a-7c are schematic views showing blasting of a slot for an initial first stope ring.

FIG. 8 is a schematic diagram showing some features relating to an apparatus for assisting a designer to design charging and blasting.

FIG. 9 is a schematic diagram demonstrating swelling of rock material when being blasted and comparison to a free volume intended to receive the blasted rock material.

FIGS. 10a and 10b are schematic views of two display views presented for a designer regarding a first stope ring comprising a slot with a first blast section.

FIG. 11 is a schematic view showing division of a first stope ring into several blast sections.

FIGS. 12a and 12b are schematic views demonstrating how an emphasized blast section of a first stope ring is visible in a side view and top view on a display device.

FIGS. 13a and 13b are schematic views demonstrating display views of a blast section of a second stope ring following a first stope ring.

For the sake of clarity, the figures show some embodiments of the disclosed solution in a simplified manner. In the figures, like reference numerals identify like elements.

### DETAILED DESCRIPTION

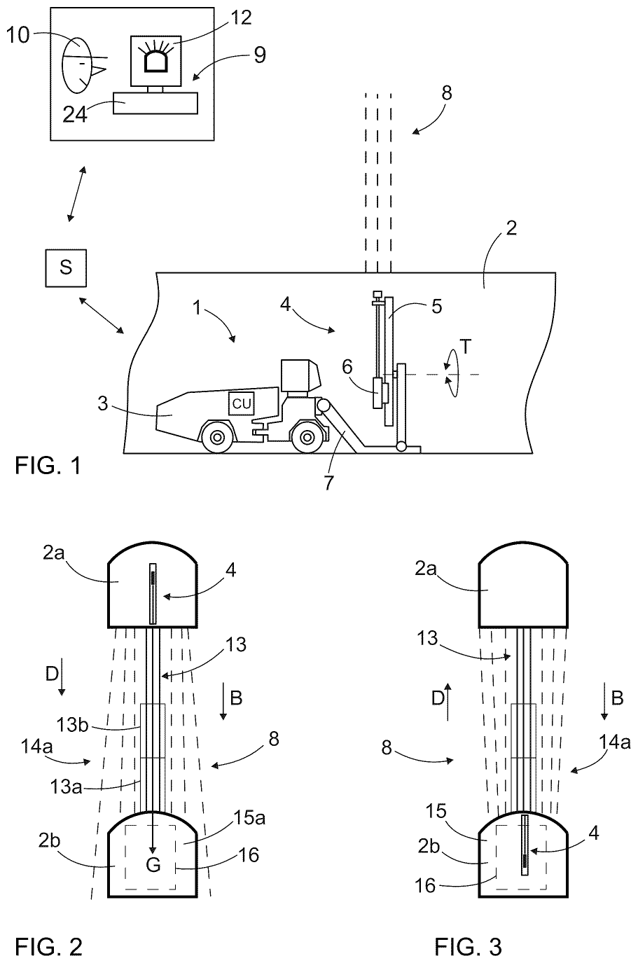

FIG. 1 illustrates a rock drilling rig 1 for executing long hole drilling for providing blast holes for stope excavation purposes in underground mining. The rock drilling rig 1 is operating in a pre-made drift 2 and includes a movable carrier 3 and a rock drilling unit 4 mounted to the carrier 3. The rock drilling unit 4 includes a feed beam 5 and rock drilling machine 6 mounted movably on the feed beam 5. The rock drilling unit 4 is supported on drilling boom 7 and can be turned T in relation to a transverse turning axis so that drill hole fans 8 can be drilled. In FIG. 1 only three parallel drill hole fans 8 are disclosed for clarity reasons. Each drill hole fan has several drill holes having different orientations and forming an umbrella type drill hole pattern.

The rock drilling rig 1 includes a control unit CU for controlling the drilling. The control unit CU can communicate with one or more servers S or external electrical devices. The control unit CU may supply data on the realized drill holes including, for example, data on position, orientation and length of the realized drill holes. Furthermore, data on rock quality and hardness can be gathered since the rock drilling machine 6 can produce sensing data during the drilling by means of sensors sensing, for example, impact energy, feed forces etc.

The data on realized drill holes and properties of the drilled rock can be submitted to an apparatus 9 configured to provide aid for a designer 10 designing charging and blasting of vertical stope rings in a stope excavation mining process. The apparatus 9 includes a data processing device 24 for processing the received data and one or more display devices 12 for presenting visual data for the designer 10 of the realized drill holes and properties of the mine, such as ore bodies and data on the drifts 2.

FIG. 2 discloses, in a simplified manner, drilling unit 4 drilling a drill hole fan 8 from an upper drift 2a towards a vertically located lower drift 2b. Drilling direction D is thus vertically downwards. In FIG. 3 the drilling is executed from the lower drift 2b towards the upper drift 2a whereby the drilling direction D is vertically upwards. The drill hole fans 8 have a slot 13 for creating initial volume for rock material expanding in blast. The slot 13 may include drill holes with greater diameter and is indicated in FIGS. 2 and 3 with greater line thickness.

FIGS. 2 and 3 further disclose that the slot 13 can be divided into several partial slots 13a and 13b. A first partial slot 13a is blasted prior a second partial slot 13b located vertically above it. Blasting of a first stope ring 14a is initiated by blasting the first partial slot 13a towards the lower drift 2b. The lower drift 2b serves as an initial free space 15a, which is capable of receiving volume of expanded rock material 16 of the first partial slot 13a when being blasted.

The expanded rock material 16 is shown in a simplified manner by means of broken lines in FIGS. 2 and 3. The blast is done vertically downwards in a blasting direction B and gravity G assists movement of the blasted rock material towards the initial free space 15. After the blasted and expanded rock material 16 is emptied from the lower drift 2b, the second partial slot 13b can be blasted. The blasting and emptying process continues in partial blast sections. Volumes of the partial blast sections are calculated or estimated in solid non-blasted state and in blasted expanded state. The volume of the expanded rock material is compared to the volume of the free space 15 capable receiving the expanded rock material. The apparatus disclosed herein is implemented for making the calculations, estimations and comparison measures.

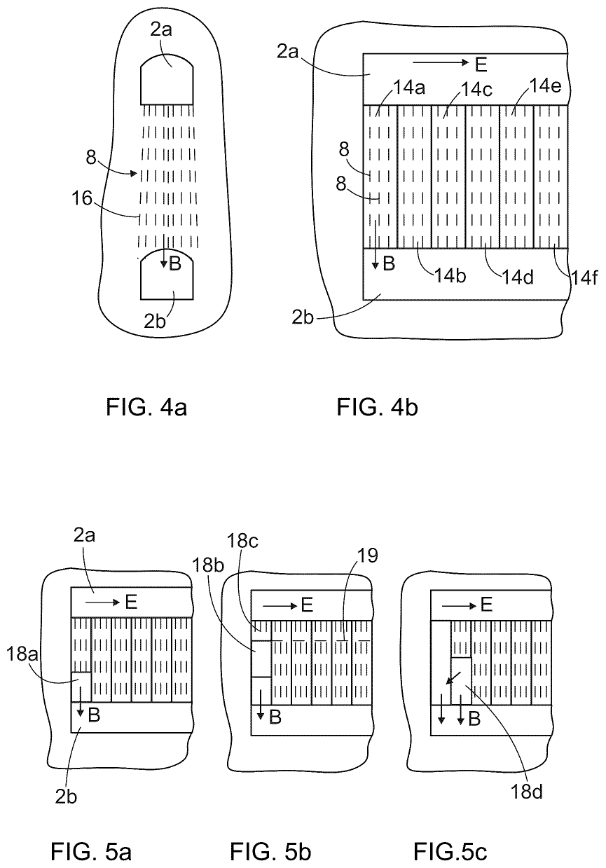

FIG. 4a discloses two horizontal drifts 2a and 2b arranged vertically one above another and drill fans 8 with several drill holes 17 drilled between them. FIG. 4b discloses in a simplified side view progress of a stope excavation process in several successive stope rings 14a-14f. The excavation process proceeds gradually forwards in an excavation direction E from a first stope ring 14a.

FIGS. 5a-5c disclose in a simplified manner a principle of dividing the stope rings 14a-14f, shown in previous FIG. 4b, into several partial blast sections, which can be blasted in accordance with a designed blasting sequence defining blasting order of the partial blast sections. In FIG. 5a a first partial blast section 18a is blasted in blast direction B to the lower drift 2b. In FIG. 5b a second partial blast section 18b with a greater volume can be blasted in blast direction B to the lower drift 2b after being emptied from rock material of the first partial blast section 18a. In FIG. 5c a third blast section 18c of the first stope ring 14a can be blasted in blast direction B with a fourth partial blast section 18d of a second stope ring 14b. Volumes of the partial blast sections 18 can increase one by one when proceeding further in the excavation direction E since volume of free space enlarges simultaneously. The apparatus disclosed in this document can be used to assistance in dividing the stope rings into suitable partial blast sections and to determine which partial blast sections are to be blasted at each blast stage.

It is also possible to leave uppermost partial blast sections, such as the shown third partial blast section 18c, of each stope ring 14 to be blasted only at a final stage whereby a kind of deck 19 (shown in broken lines in FIG. 5b) allows operation in the upper drift 2a until the deck 19 is blasted in one go.

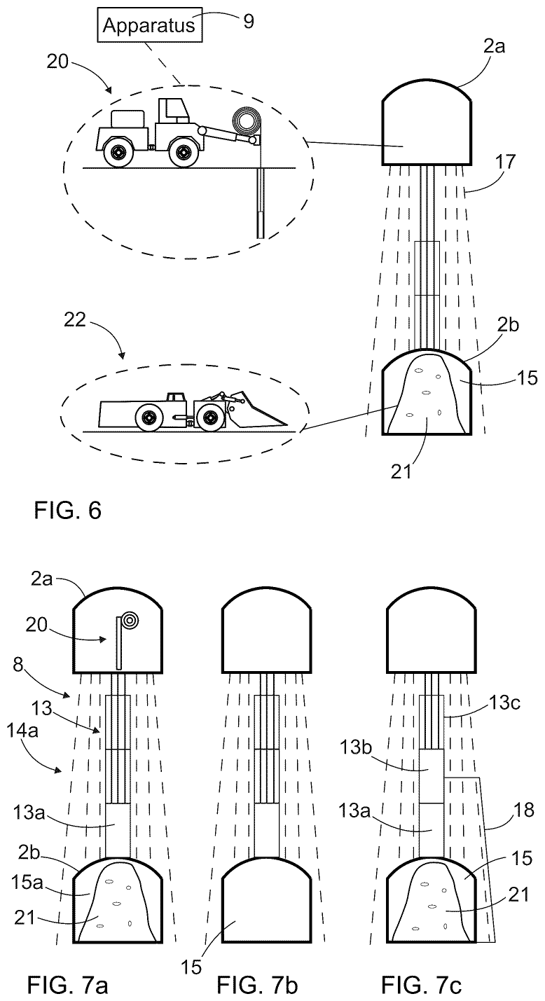

FIG. 6 discloses that the charging of drill holes 17 of drill hole fan 8 with explosive material can be done from an upper drift 2a by means of a charging device 20, such as a charging vehicle. The charging device 20 can execute the charging automatically under control of a control unit which is provided with data on charging. The data on charging can be designed in the apparatus 9 and can be communicated to the charging device 20. The charging data may include data on the amount of explosive material, mounting depths of explosive material in each drill hole 17, and delay times of detonators, for example. The charging device 20 can feed the explosive material and detonators accurately to the designed depth positions inside each drill hole 17.

After each blast a heap 21 of blasted rock material is produced. Emptying of created free space 15 can be done by means of a mining loader 22 operating at a lower drift 2b.

FIGS. 7a-7c disclose blasting of slot 13 for an initial first stope ring 14a. The slot 13 may include drill holes that belong to several parallel drill hole fans 8, thereby enough space can be formed for blasts following the blasts of the slot 13. In FIG. 7a the first stope ring 14a is charged by means of a charging device 20 and thereafter a first partial slot 13a is blasted so that a heap 21 is formed to a lower drift 2b. In FIG. 7b the heap 21 is hauled away and a greater free space including volume of the lower drift 2b and solid volume of rock material of the first partial slot 13a is created. In FIG. 7c charges in a second partial slot 13b are fired and a new heap 21 is formed. After the heap 21 is again hauled away, it is possible to blast a third partial slot 13c together with one or more additional partial blast sections 18 since there is enough free space for blasted and expanded rock material. Magnitudes of the partially blasted volumes can be estimated by the apparatus disclosed in this document.

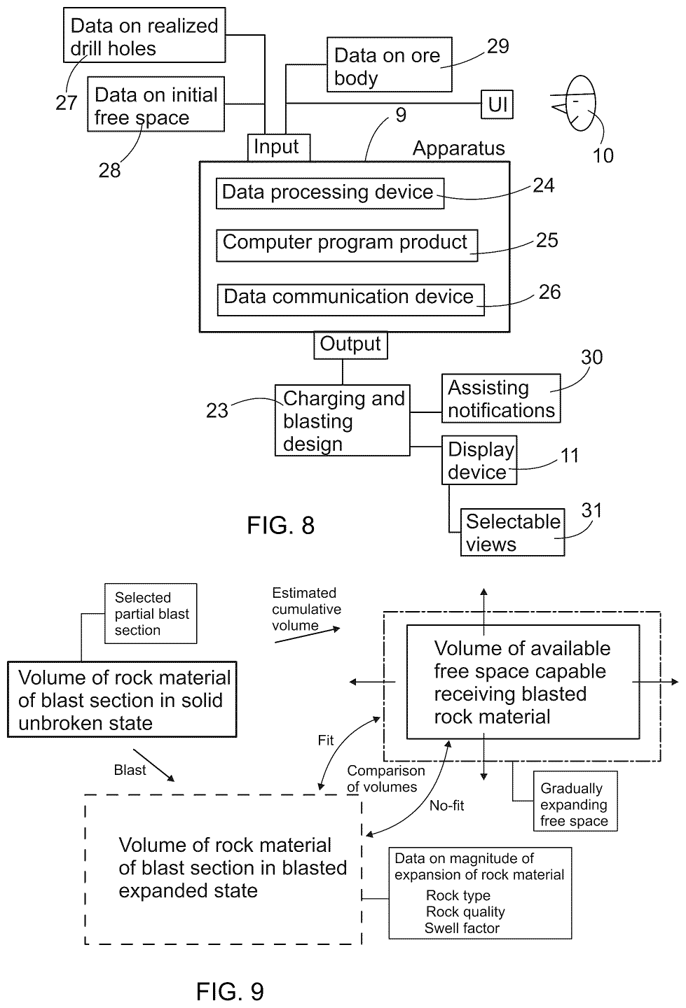

FIG. 8 discloses that a designer 10 can utilize an apparatus 9 when designing charging and blasting design 23 at an office. The design work may be executed in a computer aided manner. In other words, the designer 10 can provide parameters, selections and control commands through a user interface UI and thereby co-operate with the apparatus 9 having a data processing device 24. At least one computer program product 25 is input or retrieved to the apparatus 9 and can be executed in the data processing device 25. The computer program product 25 may be recorded on a non-transitory computer-readable media including program instructions for implementing various operations executed by the data processing device 24. Required data may be input to the data processing device 24 as individual data elements or may be retrieved from one or more memory devices. The data processing device 25 includes one or more processors or corresponding devices. Thereby, the data processing device has sufficient processing power and is capable to execute needed calculations and estimations on rock volumes and can also make needed comparisons as instructed by the computer program product and input parameters.

The apparatus 9 also includes a data communication device 26 for communication between the apparatus and one or more servers, control units, memory units, and other electrical devices. The apparatus 9 may receive data on realized drill holes 27, data on initial free space 28, data on ore body 29, and possible other data relating to the design work of a charging plan. The apparatus 9 can assist the designer 10 by providing assisting notifications 30, such as suggestions on amount of explosive material as well as mounting depths of the explosive material inside the realized drill holes.

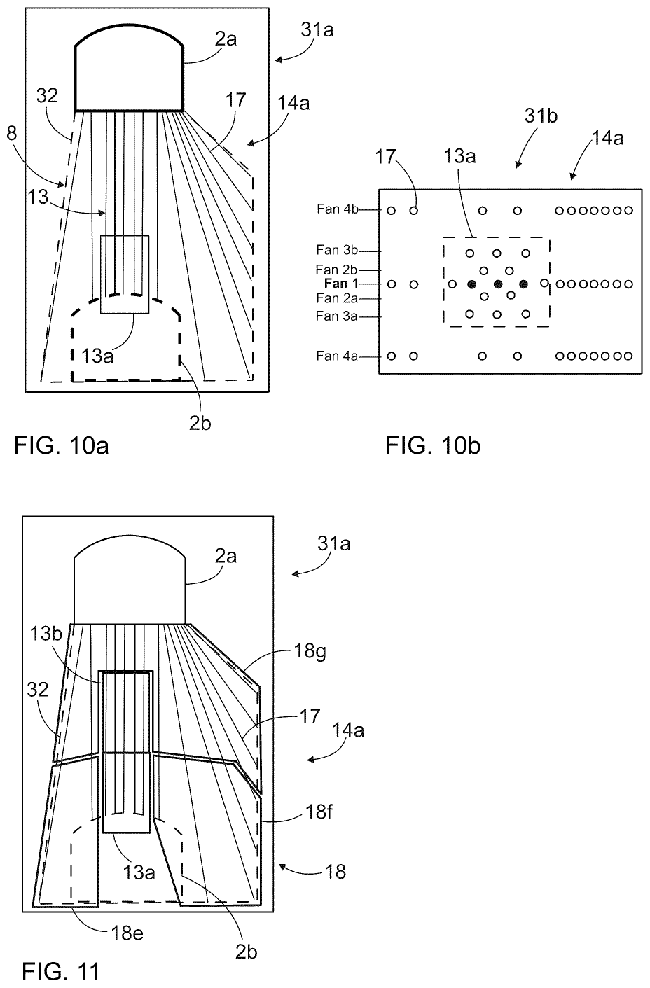

The apparatus 9 may execute automatically, or under control of the designer 10, checking measures whether size of blast sections planned by the designer 10 fit into currently available free volume when being blasted, and if not, the apparatus 9 can provide a warning or notice to the designer 10 of the situation. The apparatus 9 may also provide suggestions on how to change the charging plan and to avoid unwanted situations during the blasting phase. For the practical planning work, it is very beneficial that the apparatus 9 can present selectable views 31 on a one or more display devices of the charging plan together with realized drill hole fans and border lines of ore bodies. Examples of such display views 31 are disclosed in FIGS. 10a-13b.

The apparatus 9 may transmit the results of the designing work not only to the display device 11, but also to memory devices and via the data communication device 26 to a charging device, or anywhere else where the charging and blasting data is needed. This way, the designed charging and blasting design 23 may be displayed, stored and transmitted to desired location.

FIG. 9 is a simplified diagram demonstrating swelling of rock material when being blasted and comparison to a free volume intended to receive the blasted rock material. An apparatus can calculate or estimate volume of rock material in a solid state in response to design of a partial blast section defined by a designer. The designer can define the size of the partial blast section visually on a display device, for example. The designer can move boarder lines on the display device and the apparatus is capable of estimating updated volumes. The apparatus can also calculate or estimate volume of expanded blasted rock material in response to the estimated volume in solid state and data on magnitude of expansion of each rock type being excavated. The volume of available free space is also calculated or estimated since the free space expands gradually when blasting process of the partial blast sections proceeds.

FIG. 10a discloses a side view 31a of a charging plan seen in a longitudinal direction of drifts 2a and 2b. The side view is a presentation of realized drill holes 17 in drill fan pattern 8 and in relation to the outlines of the horizontal drifts 2a, 2b and boundaries 32 of the ore body. The boundaries 32 are shown in broken lines. As can be seen the realized drill holes 17 are orientated in the drill hole fan 8 in accordance with the boundaries 32, as well as the lengths thereof. In FIG. 10a a first stope ring 14a including a slot 13 with a first partial slot 13a is shown. The first partial slot 13a is an initial first partial blast section to be blasted.

FIG. 10b discloses a top view 31b, which can be presented simultaneously on a display device for the designer. The top view 31b shows the presentation of start points of the realized drill holes 17 belonging to several parallel drill hole fans, Fan 1-Fan 4b, of the first stope ring 14a. As can be seen, the first partial slot 13a includes several drill holes 17 being part of several neighboring fans, Fan 1-Fan 3b. Drill holes with black filling indicate that they are not blast holes but are drill holes with a greater diameter and are configured to provide space for the first blast section.

A designer can in co-operation with the apparatus determine, for example, vertical dimensions of the first partial slot 13a. The apparatus informs the designer if too big a volume is included and can make a proposal for the designer. When approved by the designer, the apparatus can determine the amount of explosive material needed for blasting the first partial slot 13a. The apparatus can also determine the insertion depth of the explosive material for each blast hole of the first partial slot. Further, the apparatus can determine delay times for the explosive material inserted into the blast holes for controlling firing of the explosives.

FIG. 11 discloses a side view 31a of a first stope ring 14a, which is divided into several blast sections 18, 13a, 13b, 18e, 18f and 18g. There is a first partial slot 13a and a second partial slot 13b above it. The partial slots 13a, 13b are blast sections 18, which are detonated before other blast sections 18e, 18f and 18g. A designer can set borders of the blast sections 18e, 18f and 18g in co-operation with an apparatus assisting the design work. Border lines can be moved on the display device and the apparatus updates estimated volumes of the blast sections 18. Thereby the designed work is intuitive.

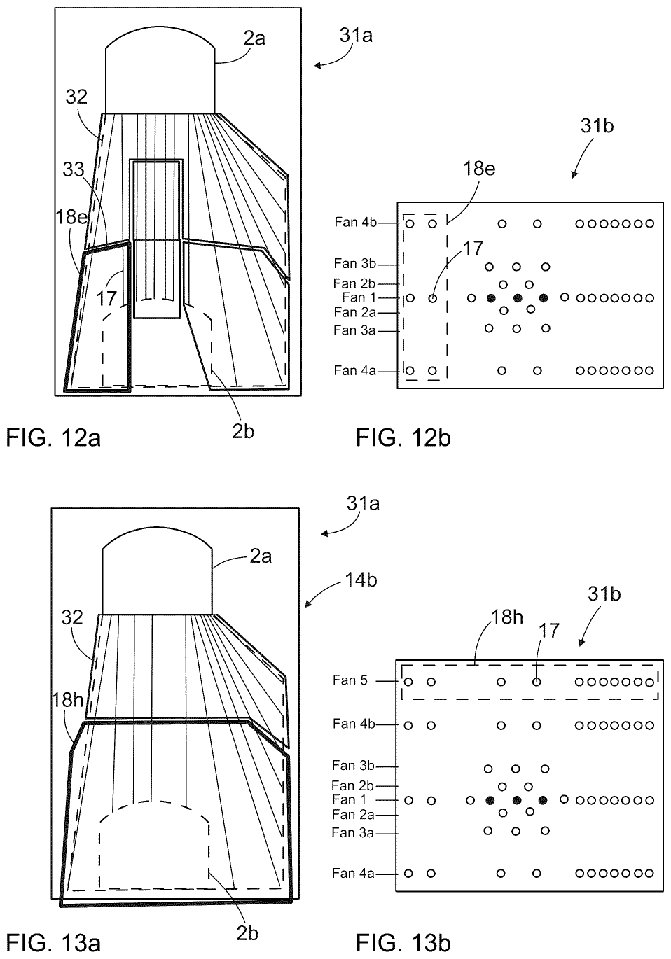

FIG. 2b discloses as an example how the blast section 18e shown in FIG. 11 and emphasized in FIG. 12a can be shown in a top-view 31b presentation. If, for example, an upper boarder line 33 of the blast section 18e is moved vertically upwards or downwards, or if its orientation is amended, an apparatus assisting a designer can update volume estimations and can also update charging amounts and height locations of the explosive inside the drill holes 17.

FIGS. 13a and 13b disclose display views 31a, 31b of a blast section 18h of a second stope ring 14b following a first stope ring 14a shown in previous FIGS. 10a-12b. The designer can also in this case make amendments to borders limiting the blast section 18h and the apparatus provides the designer with assisting data for making the amendments and decisions. When the design is approved by the designer, the apparatus can calculate the amount of explosive material, insertion depths, firing orders and delays, for example.

Although the present embodiment(s) has been described in relation to particular aspects thereof, many other variations and modifications and other uses will become apparent to those skilled in the art. It is preferred therefore, that the present embodiment(s) be limited not by the specific disclosure herein, but only by the appended claims.

1. An apparatus comprising:
at least one data processing device arranged for assisting designing charging and blasting of downwards or upwards directed drill holes of a plurality of vertical stope rings in a stope excavation in an underground mine, wherein each stope ring includes at least two drill hole fans provided with a plurality of drill holes,
wherein the apparatus is provided with data on realized drill holes drilled for a stope and data on an initial free space located at least partly below the stope,
wherein the apparatus is configured to assist in dividing an initial first stope ring into a plurality of blast sections, which are configured to be blasted in several partial blasts towards an available free space including at least the initial free space,
wherein the apparatus is configured to estimate a volume of rock material of selected blast sections of the plurality of blast sections in a solid non-blasted state and in a blasted expanded state,
wherein the apparatus is configured to estimate a volume of the available free space at the first stope ring, and
wherein the apparatus is configured to compare the volume of rock material of the selected blast section in the blasted expanded state to the volume of the available free space and is, the apparatus being configured to indicate, based on the comparison, when the selected blast section fits in the blasted expanded state into the available free space.

2. The apparatus as claimed in claim 1, wherein the apparatus is further configured to assist designing a slot for the first stope ring and to assist in dividing the slot into at least two partial slots one on top of the other, wherein a first partial slot is closest to the initial free space and is provided with a prior blasting order to a second partial slot vertically above the first partial slot, and the apparatus is configured to estimate the volume of rock material in the blasted expanded state of the first partial slot and to compare the estimated volume to the volume of the initial free space.

3. The apparatus as claimed in claim 1, wherein the apparatus is configured to provide on a display device at least two selectable views of the first stope ring in different view angles, and to define and present the plurality of blast sections of the first stope ring in response to instructions input to the apparatus.

4. The apparatus as claimed in claim 3, wherein the apparatus is configured to present, at least in one of the views, the drill holes in relation to limiting elements selected from: outlines of a horizontal lower drift serving as the initial free space; outlines of a horizontal upper drift serving as a passage for the charging and comprising openings of the drill holes; and boundary lines of an ore body at the first stope ring.

5. The apparatus as claimed in claim 4, wherein the apparatus is configured to provide on a display device a top view and a side view of drill holes of the first stope ring, wherein the top view includes a presentation of start points and projections of angles of the drill holes, and wherein the side view includes a presentation of the drill holes in a fan pattern and in relation to the outlines of the horizontal drifts and the boundaries of the ore body.

6. The apparatus as claimed in claim 1, wherein the apparatus is provided with realized data on drill holes drilled for the first stope ring, and wherein the realized data includes properties of the drilled rock material surrounding the drill holes of the first stope ring, whereby the apparatus is configured to take the rock data into account when estimating the amount of the expansion of the rock material of each blast section of the first stope ring.

7. The apparatus as claimed in claim 1, wherein the apparatus is configured to provide a designer advice for setting boarders of the selected blast section so that the volume of the selected blast section in the blasted state matches with the available free space on the basis of the executed comparison.

8. The apparatus as claimed in claim 1, wherein the apparatus is configured to determine a charging depth for drill holes of the first stope ring based on realized drill data of the drill holes and set boarders of the blast sections.

9. A method for assisting designing charging and blasting of drill holes of a plurality of vertical stope rings in a stope excavation in an underground mine, wherein each stope ring includes at least two drill hole fans provided with a plurality of drill holes, the method comprising:
using at least one data processing device in the designing process;
receiving data on realized drill holes drilled for a stope;
receiving data on an initial free space located at least partly below the stope;
assisting in dividing an initial first stope ring into a plurality of blast sections, which are configured to be blasted in several partial blasts towards an available free space including at least the initial free space;
estimating a volume of rock material of selected blast sections of the plurality of blast sections in a solid non-blasted state and in a blasted expanded state;
estimating a volume of the available free space at the first stope ring;
comparing the volume of the selected blast section in the blasted expanded state to the volume of the available free space; and
indicating, based on the comparison, when the selected blast section fits in the blasted expanded state into the available free space.
